(19) United States
(12) Patent Application Publication
(10) Pub. No.: US 2009/0121710 A1
(43) Pub. Date: May 14, 2009

(54) Novel free layer design for TMR/CPP device

(75) Inventors: Hui-Chuan Wang, Pleasanton, CA (US); Tong Zhao, Fremont, CA (US); Kunliang Zhang, Fremont, CA (US); Min Li, Dublin, CA (US)

Correspondence Address: SAILE ACKERMAN LLC, 28 DAVIS AVENUE, POUGHKEEPSIE, NY, 12603, US

(73) Assignee: Headway Technologies, Inc.

(21) Appl. No.: 11/983,718

(22) Filed: Nov. 9, 2007

(51) Int. Cl. G01R 33/09; G01R 3/00; H01L 21/00

(52) U.S. Cl. 324/252; 438/3; 257/E21.001

(57) ABSTRACT

A TMR sensor and a CPP GMR sensor all include a free layer that is of the form CoFeₓB_{y}/non-magnetic layer/NiFe_{z} or of the form CoFe/CoFeB/non-magnetic layer/NiFe, where, in one embodiment, the thickness of the non-magnetic layer is less than approximately 15 angstroms and the atom percentage x, z of Fe can vary between 0 and 70% for x and 0 and 100% for z and the atom percentage, y, of B can vary between 0 and 30%. This arrangement can produce a 5-10% improvement in dR/R and can allow the coupling field between the CoFeB and the NiFe to be strong enough that an in-stack biasing of the CoFeB layer occurs and the hysteresis behavior and stability of the sensor is improved.

### RELATED PATENT APPLICATION

This patent application is related to Docket Number HMG 06-040, Ser. No. ______, Filing Date ______, assigned to the same assignee as the present invention and which is incorporated by reference herein in its entirety.

### BACKGROUND OF THE INVENTION

1. Field of the Invention

This invention relates generally to magnetoresistive read sensors and particularly to the free layer formations of such sensors operating in a tunneling magnetoresistive (TMR) configuration and current-perpendicular-to- plane (CPP) GMR configurations.

2. Description of the Related Art

In simplest form, the usual giant magnetoresistive (GMR) read sensor consists of two magnetic layers, formed vertically above each other in a parallel planar configuration and separated by a conducting, but non-magnetic, spacer layer. Each magnetic layer is given a unidirectional magnetic moment within its plane and the relative orientations of the two planar magnetic moments determines the electrical resistance that is experienced by a current that passes from magnetic layer to magnetic layer through the spacer layer. The physical basis for the GMR effect is the fact that the conduction electrons are spin polarized by interaction with the magnetic moments of the magnetized layers. This polarization, in turn, affects their scattering properties within the layers and, consequently, results in changes in the resistance of the layered configuration. In effect, the configuration is a variable resistor that is controlled by the angle between the magnetizations.

The magnetic tunneling junction device (TMR device) is an alternative form of GMR sensor in which the relative orientation of the magnetic moments in the upper and lower magnetized layers controls the flow of spin-polarized electrons tunneling through a very thin dielectric layer (the tunneling barrier layer) formed between those magnetized layers. When injected electrons pass through the upper layer, as in the GMR device, they are spin polarized by interaction with the magnetization direction (direction of its magnetic moment) of that electrode. The probability of such an electron then tunneling through the intervening tunneling barrier layer into the lower magnetic layer then depends on the availability of states within the lower electrode which the tunneling electron can occupy. This number, in turn, depends on the magnetization direction of the lower electrode. The tunneling probability is thereby spin dependent and the magnitude of the current (tunneling probability times number of electrons impinging on the barrier layer) depends upon the relative orientation of the magnetizations of magnetic layers above and below the barrier layer.

In what is called a spin-filter configuration, one of the two magnetic layers in both the GMR and TMR has its magnetization fixed in spatial direction (the pinned layer), while the other layer (the free layer) has its magnetization free to move in response to an external magnetic stimulus. If the magnetization of the free layer is allowed to move continuously, as when it is acted on by a continuously varying external magnetic field, the GMR and TMR device each effectively acts as a variable resistor and it can be used as a read-head in a hard disk drive. If the magnetization of the free layer is only permitted to take on two orientations, parallel and antiparallel to that of the pinned layer, then the device can be used to store information as an MRAM cell.

The difference in operation between the GMR sensor discussed first, and the TMR sensor just now discussed, is that the resistance variations in the former are a direct result of changes in the electrical resistance (due to spin polarized electron scattering) within the three-layer configuration (magnetic layer/non-magnetic, conducting layer/magnetic layer), whereas in the TMR sensor, the amount of current is controlled by the availability of states for electrons that tunnel through the dielectric barrier layer that is formed between the free and pinned layers.

When used as a read head, (called a TMR read head, or “tunneling magnetoresistive” read head) the free layer magnetization is moved by the influence of the external magnetic fields of a recorded medium, such as is produced by a moving hard disk or tape. As the free layer magnetization varies in direction, a sense current passing between the upper and lower electrodes and tunneling through the dielectric barrier layer varies in magnitude as more or less electron states become available. Thus a varying voltage appears across the electrodes. This voltage, in turn, is interpreted by external circuitry and converted into a representation of the information stored in the medium.

A typical spin-filter GMR sensor structure is the following:

Seed/AFM/outer pinned/Ru/inner pinned/Cu/Free Layer/Capping Layer.

A typical spin-filter TMR sensor structure is the following:

Seed/AFM/outer pinned/Ru/inner pinned/MgO/Free Layer/Capping Layer,

In the TMR configuration shown above (and in the CPP GMR as well), the seed layer is an underlayer required to form subsequent high quality magnetic layers. The AFM (antiferromagnetic layer) is required to pin the pinned layer, ie., to fix the direction of its magnetic moment by exchange coupling. The pinned layer itself is now most often a synthetic antiferromagnetic (SyAF) (also termed a synthetic antiparallel (SyAP)) structure with zero total magnetic moment. This structure is achieved by forming an antiferromagnetically coupled tri-layer denoted herein as “outer pinned/Ru/inner pinned”, which is to say that two ferromagnetic layers, the outer and inner pinned layers, are magnetically coupled across a Ru spacer layer in such a way that their respective magnetic moments are mutually antiparallel and substantially cancel each other. The structure and function of such SyAP structures is well known in the art and will not be discussed in further detail herein. The conducting, but non-magnetic Cu spacer layer of a GMR is replaced in the TMR by (for example) a thin insulating layer of oxidized magnesium that can be oxidized in any of several different ways to produce an effective dielectric tunneling barrier layer. The free layer in both the GMR and TMR is usually a bilayer of ferromagnetic material such as CoFeB/NiFe, and the capping layer in both the GMR and TMR is typically a layer of tantalum (Ta). The bilayer choice for the free layer is strongly suggested by the fact that an effective free layer should be magnetically soft (of low coercivity), which is an attribute of the CoFeB layer. The CoFeB layer, however, exhibits excessive magnetostriction. By adding the NiFe layer, the magnetostriction is reduced, but unfortunately, the TMR ratio, dR/R, (ratio of maximum resistance variation as the free layer magnetic moment changes direction, dR, to total device resistance, R), which is a measure of its efficacy as a read sensor, will also be reduced. We shall see below that the structure of the free layer can be significantly altered to provide an improved TMR sensor.

Much recent experimentation on GMR sensors has been directed at improvements in the free layer structure. The most common structure in both the GMR and TMR sensor had been a CoFeB/NiFe bilayer, in which the NiFe layer provides the low magnetostriction, while the CoFeB provides good magnetic softness. More recently, work has been done on improving the magnetic properties of both free and pinned layers by utilizing novel materials and laminated structures.

Invention disclosure, docket number HMG 06-040 (Guo et al—Headway) shows a free layer comprising CoFeB/Ta/CoFeB.

U.S. Pat. No. 7,149,105 (Brown et al) discloses a free layer comprising NiFe and CoFeB separated by a nonmagnetic spacer such as Ru, having a thickness of 2-30 Angstroms.

U.S. Patent Application 2007/0097561 (Miyauchi et al) shows a free layer comprising alloys of Co, Fe, Ni having a nonmagnetic layer in between.

U.S. Patent Application 2006/0291108 (Sbiaa et al) describes a free layer containing a nonmagnetic spacer such as Ru, Rh, Ag Cu.

### SUMMARY OF THE INVENTION

A first object of this invention is to provide a method of forming a TMR or CPP GMR sensor that combines a high TMR or GMR ratio and a low free layer coercivity while retaining other advantageous properties.

A second object of this invention is to provide such a sensor that contains a free layer structure wherein the coupling strength between two component ferromagnetic layers is adjustable.

A third object of this invention is to provide such a free layer structure wherein a magnetic coupling between two component ferromagnetic layers provides an in-stack biasing of one of the layers.

A fourth object of this invention is to provide such a free layer structure wherein hysteresis and non-linearity in one of the component ferromagnetic layers is reduced.

This object will be met, in one embodiment, by the formation within either the CPP or TMR sensors of a tri-layered free layer in which a thin (0-15 angstroms) non-magnetic layer is interposed between a layer of CoFeₓ B_{y} and a layer of NiFe,:

CPP structure: CoFeₓ B_{y}/(Hf, V, Zr, Nb, Ta, Mo, Cr, . . . )/ NiFe_{z}

where percentages x (less than 70%), y (less than 30%) and z (less than 100%) refer respectively to atom percentages of Fe, B and Fe and Hf, V, Zr, Nb, Ta, Mo, Cr, are suitable non-magnetic layers to be formed in thicknesses less than 15 angstroms.

It is asserted that the free layer formed in this way will be improved in TMR by between 5% and 10%, while retaining such other advantageous properties of a free layer as usable areal resistance (RA). In addition, if a layer of NiFe with very negative magnetostriction is used, then, after lapping of the ABS, the magnetization of the NiFe will be aligned parallel to the ABS the resulting coupling field of the structure will act as a uniformly distributed biasing field for the CoFeB layer by the magnetic coupling across the non-magnetic layer. This will help in eliminating hysteresis and non-linearity in the magnetic switching of the CoFeB free layer and, thereby, reduce yield losses related to instability.

The correlation between CoFeB/NiFe coupling energy and thickness of an interposed non-magnetic Ta layer is shown in FIG. 1. The abscissa is Ta thickness in angstroms and the ordinate is coupling energy in units of 10⁻³ ergs/cm². As the graph clearly shows, the coupling energy increases strongly as the thickness of the Ta layer decreases. This increased coupling energy will provide an effective in-stack biasing, with no external biasing layers needed, of the CoFeB layer.

Table 1 below shows the improvement in dR/R produced by the CoFeB/Ta/NiFe free layer when it is incorporated within a TMR structure:

Seed/AFM/outer pinned/Ru/inner pinned/MgO/CoFeB/x-Ta/NiFe/cap

Here, x is the thickness of the interposed Ta layer and it takes on the values: x=0, 3, 5, 10 angstroms. For comparison purposes, the last row (row 5) is the performance of a typical CoFe/NiFe free layer, which has the lowest value of dR/R. The first row (row 1) is the performance of a CoFeB/NiFe layer with no Ta interposed. The three rows where Ta is interposed with thicknesses of 3, 5 and 10 angstroms (rows 2, 3 and 4), show the desired improvements of dR/R over both the CoFeB/NiFe and the CoFe/NiFe layers.

TABLE 1

| Free Layer Structure | dR/R | RA(Ωμm²) |
|---|---|---|
| CoFeB/NiFe | 61% | 2.30 |
| CoFeB/3 Angstroms Ta/NiFe | 64% | 2.10 |
| CoFeB/5 Angstroms Ta/NiFe | 64% | 2.20 |
| CoFeB/10 Angstroms Ta/NiFe | 65% | 2.30 |
| CoFe/NiFe (reference) | 52% | 2.30 |

### BRIEF DESCRIPTION OF THE DRAWINGS

FIG. 1 is a graph showing the coupling energy between CoFeB and NiFe when a Ta layer is interposed between them

FIG. 2A is a schematic representation a TMR stack (or CPP GMR stack) that includes the CoFeB/Ta/NiFe free layer of the present invention.

FIG. 2B is a schematic representation of a TMR stack (or a CPP GMR stack) that includes a four-layer free layer.

### DESCRIPTION OF THE PREFERRED EMBODIMENTS

The preferred embodiment of the present invention is a TMR or CPP GMR sensor structure of good areal resistance, good free layer coercivity, improved magnetoresistive ratio (dRJR), adjustable magnetostriction and improved stability and hysteresis control resulting from in-stack biasing. This improvement is obtained by the introduction of a tri-layer (or four-layer) free layer comprising a CoFeB layer and an NiFe layer between which is interposed a thin layer of a non-magnetic material, such as Hf, V, Zr, Nb, Ta, Mo, or Cr, that is formed to a thickness between approximately 0 and 15 angstroms.

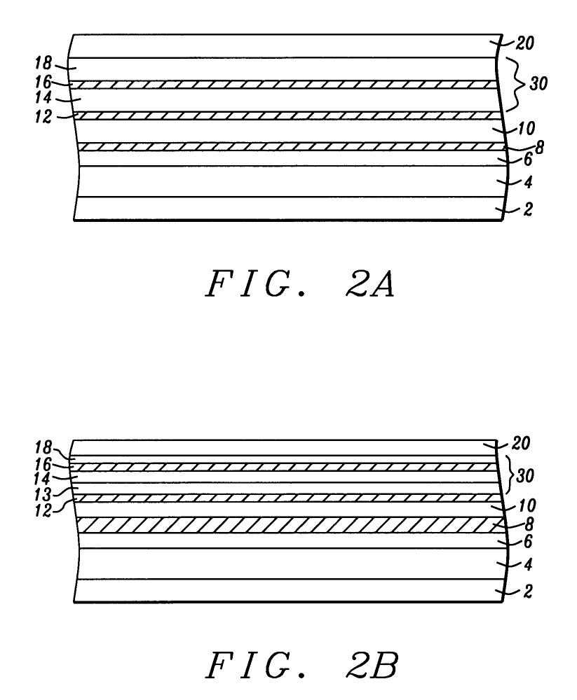

Referring to FIG. 2A, there is shown schematically a TMR stack of the general form into which the tri-layered free layer of the present invention can be introduced so as to meet the objects of the invention. In the figure there is seen a seed layer (2) an antiferromagnetic pinning layer (4), a tri-layered pinned layer that comprises an outer pinned layer (6) a Ru coupling layer (8) and an inner pinned layer (10), a tunneling barrier layer (12) which is preferably a layer of MgO (or, in the case of a CPP GMR stack, a layer of Cu), a tri-layered free layer (30) comprising two ferromagnetic layers (14) and (18) between which is interposed a non-magnetic layer (16), and a capping layer (20). This free layer (30) of the device is, therefore, generally of the form:

CoFeₓ B_{y}/(Hf, V, Zr, Nb, Ta, Mo, Cr, . . . )/NiFe_{z}

The subscripts x, y and z denote atom percentages of the Fe and B in the CoFeB and the Fe in the NiFe. The CoFeB layer is layer (14) in FIG. 2A, the NiFe layer is layer (18) in FIG. 2 and the layer that can be a layer of non-magnetic material such as Hf, V, Zr, Nb, Ta, Mo or Cr is layer (16) of FIG. 2A.

Referring to FIG. 2B, there is shown the same layer structure of FIG. 2A with the inclusion of an additional ferromagnetic layer (13) of CoNiFeB in the free layer (30). Thus, the free layer is of the form

CoNiFeB/CoFeₓ B_{y}/(Hf, V, Zr, Nb, Ta, Mo, Cr, . . . )/NiFe_{z}

According to our results, insertion of the non-magnetic layer in the configuration of FIG. 2A while making a choice of x between approximately 0 and 70%, y between approximately 0 and 30% and z between approximately 0 and 100%, the TMR ratio will increase between approximately 5 to 10% while maintaining all other generally good properties of the device such as its areal resistance. This TMR improvement while retaining good areal resistance is shown in Table 1 above.

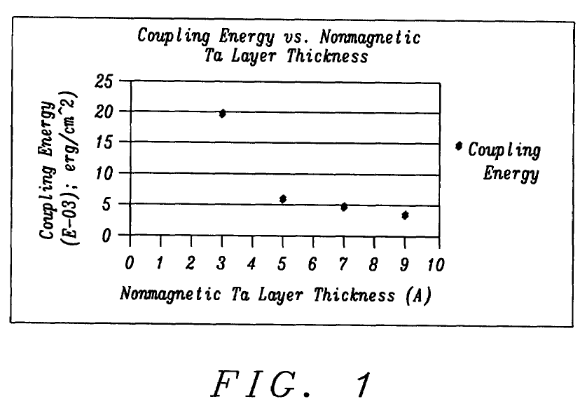

Further, according to our experimental results, by varying the non-magnetic layer in thickness among the materials such as (Hf, V, Zr, Nb, Ta, Mo, Cr, . . . ), with the possibility of including a third ferromagnetic layer (13) such as CoNiFeB in the free layer (30) structure of FIG. 2B, while making a choice of x between approximately 0 and 70%, y between approximately 0 and 30% and z between approximately 0 and 100%, will allow the coupling energy between the CoFeB and NiFe to be varied as shown in FIG. 1 Further yet, according to our experimental results, varying the non-magnetic layer in thickness among the materials such as (Hf, V, Zr, Nb, Ta, Mo, Cr, . . . ), while making a choice of x between approximately 0 and 70%, y between approximately 0 and 30% and z between approximately 0 and 15%, will produce an NiFe layer of negative magnetostriction. After lapping the ABS (air bearing surface) of the sensor, the effect of that lapping on the NiFe layer will produce a magnetization parallel to the lapped ABS surface. The coupling between this field and the CoFeB layer will, thereby, produce what is effectively a uniformly distributed biasing field along the CoFeB layer. This field will stabilize the domain structure of the CoFeB layer and fix its bias point, thereby helping to eliminate hysteresis and non-linearity in the magnetic switching of the CoFeB layer.

Further yet, according to our experimental results, varying the non-magnetic layer in thickness among the materials such as (Hf, V, Zr, Nb, Ta, Mo, Cr, . . . ), with the possibility of including a third ferromagnetic layer (13) such as CoFe, in the free layer (30) structure of FIG. 2B, to produce a free layer of the form:

CoFeₓ/CoFe_{y}B_{z}/(Hf, V, Zr, Nb, Ta, Mo, Cr, . . . )/NiFeₐ

while making a choice of x between approximately 0 and 100%, y between approximately 0 and 70% and z between approximately 0 and 30% and a between approximately 0 and 100%, will also allow the coupling energy between the CoFeB and NiFe to be varied as shown in FIG. 1.

Further yet, according to our experimental results, varying the non-magnetic layer in thickness among the materials such as (Hf, V, Zr, Nb, Ta, Mo, Cr, . . . ), with the possibility of including a third ferromagnetic layer such as CoNiFeB in the free layer structure (as if FIG. 2B), to produce a free layer of the form:

FeNiₓ/CoFe_{y}B_{z}/(Hf, V, Zr, Nb, Ta, Mo, Cr, . . . )/NiFeₐ

while making a choice of x between approximately 0 and 40%, y between approximately 0 and 70% and z between approximately 0 and 30% and a between approximately 0 and 100%, will also allow the coupling energy between the CoFeB and NiFe to be varied as shown in FIG. 1.

It is to be noted that although the above embodiments have been exemplified by reference to the layer structure of a TMR sensor, we have found that the free layer described therein will also improve the performance of a CPP configured GMR sensor in a similar fashion and for similar reasons. In short, FIGS. 2A and 2B can equally well be interpreted as representing a CPP GMR sensor, a difference being the replacement of the tunneling barrier layer (12) by a conducting spacer layer such as a layer of Cu.

As is understood by a person skilled in the art, the preferred embodiments of the present invention are illustrative of the present invention rather than limiting of the present invention. Revisions and modifications may be made to methods, materials, structures and dimensions employed in forming and providing a TMR or a CPP GMR or a sensor incorporating a tri-layered or four layered composite free layer, while still forming and providing such a device and its method of formation in accord with the spirit and scope of the present invention as defined by the appended claims.

What is claimed is:

1. A TMR sensor element comprising:
a seed layer;
a pinning layer formed on said seed layer;
a pinned layer formed on said pinning layer and magnetically coupled thereto;
a tunneling barrier layer formed on said pinned layer;
a multi-layered composite free layer further comprising:
a layer of CoFeₓ B_{y}
a layer of non-magnetic material between 0 and 15 angstroms in thickness;
a layer of NiFe_{z}
a capping layer formed on said free layer; wherein,
the thickness of said non-magnetic layer determines the coupling energy between said layer of CoFeₓ B_{y} and said layer of NiFe,; and wherein
x is an atomic percent of Fe and is between approximately 0 and 70 and
y is the atomic percent of B and is between approximately 0 and 30 and
z is an atomic percent of Fe and is between approximately 0 and 100.

2. The sensor of claim 1 where said non-magnetic layer is a layer of Hf, V, Zr, Nb, Ta, Mo or Cr.

3. A TMR sensor element comprising:
a seed layer;
a pinning layer formed on said seed layer;
a pinned layer formed on said pinning layer and magnetically coupled thereto;
a tunneling barrier layer formed on said pinned layer;
a multi-layered composite free layer further comprising:
a layer of CoFeₓ B_{y};
a layer of non-magnetic material between 0 and 15 angstroms in thickness;
a layer of NiFe_{z};
a capping layer formed on said free layer; wherein,
the thickness of said non-magnetic layer determines the coupling energy between said layer of CoFeₓ B_{y} and said layer of NiFe_{z}; and wherein
x is an atomic percent of Fe and is between approximately 0 and 70 and
y is the atomic percent of B and is between approximately 0 and 30 and
z is an atomic percent of Fe and is between approximately 0 and 30, whereby said layer of NiFe_{z} has a very negative magnetostriction and whereby the magnetization of NiFe_{z} is set by lapping and is coupled to the magnetization of CoFeₓ B_{y} providing a biasing thereof.

4. The sensor of claim 3 where said non-magnetic layer is a layer of Hf, V, Zr, Nb, Ta, Mo or Cr.

5. A TMR sensor element comprising:
a seed layer;
a pinning layer formed on said seed layer;
a pinned layer formed on said pinning layer and magnetically coupled thereto;
a tunneling barrier layer formed on said pinned layer;
a multi-layered composite free layer further comprising:
a layer of CoFeₓ;
a layer of CoFe_{y} B_{z};
a layer of non-magnetic material between 0 and 15 angstroms in thickness;
a layer of NiFeₐ;
a capping layer formed on said free layer; wherein,
the thickness of said non-magnetic layer determines the coupling energy between said layer of CoFeₓ B_{y} said layer of layer of CoFeₓ and said layer of NiFe_{z}; and wherein
x is an atomic percent of Fe and is between approximately 0 and 100 and
y is an atomic percent of Fe and is between approximately 0 and 70 and
z is the atomic percent of B and is between approximately 0 and 30 and
a is an atomic percent of Fe and is between approximately 0 and 100.

6. The sensor of claim 5 where said non-magnetic layer is a layer of Hf, V, Zr, Nb, Ta, Mo or Cr.

7. A TMR sensor element comprising:
a seed layer;
a pinning layer formed on said seed layer;
a pinned layer formed on said pinning layer and magnetically coupled thereto;
a tunneling barrier layer formed on said pinned layer;
a multi-layered composite free layer further comprising:
a layer of FeNiₓ;
a layer of CoFe_{y} B_{z};
a layer of non-magnetic material between 0 and 15 angstroms in thickness;
a layer of NiFeₐ;
a capping layer formed on said free layer; wherein,
the thickness of said non-magnetic layer determines the coupling energy between said layer of NiFeₐ, said layer of FeNiₓ and said layer of CoFe_{y} B_{z}; and wherein
x is an atomic percent of Ni and is between approximately 0 and 40 and
y is an atomic percent of Fe and is between approximately 0 and 70 and
z is the atomic percent of B and is between approximately 0 and 30; and
a is an atomic percent of Fe and is between approximately 0 and 100.

8. The sensor of claim 7 where said non-magnetic layer is a layer of Hf, V, Zr, Nb, Ta, Mo or Cr.

9. A method of forming a TMR sensor element having in-stack free layer biasing and a varying coupling energy between ferromagnetic layers of a composite free layer comprising:
providing a seed layer;
forming a pinning layer on said seed layer;
forming a pinned layer on said pinning layer;
forming a tunneling barrier layer on said pinned layer;
forming a multi-layered composite free layer on said tunneling barrier layer, said formation further comprising:
forming a layer of CoFeₓ B_{y} on said tunneling barrier layer;
forming a layer of non-magnetic material between 0 and 15 angstroms in thickness on said layer of CoFeₓ B_{y};
forming a layer of NiFe_{z} on said layer of non-magnetic material;
forming a capping layer on said free layer; wherein,
x is an atomic percent of Fe and is between approximately 0 and 70 and
y is the atomic percent of B and is between approximately 0 and 30 and
z is an atomic percent of Fe and is between approximately 0 and 15, whereby said layer of NiFe, has a very negative magnetostriction; then
setting a magnetization of NiFe_{z} parallel to an ABS of said sensor by lapping said ABS of said sensor, whereby said magnetization is coupled to a magnetization of CoFeₓB_{y} providing a biasing thereof.

10. The method of claim 9 where said non-magnetic layer is a layer of Hf, V, Zr, Nb, Ta, Mo or Cr.

11. The method of claim 9 wherein the energy of said coupling between said magnetization of NiFe_{z} and said magnetization of CoFeₓ B_{y} is varied by varying the thickness of said non-magnetic layer.

12. A CPP GMR sensor element comprising:
a seed layer;
a pinning layer formed on said seed layer;
a pinned layer formed on said pinning layer and magnetically coupled thereto;
a conducting spacer layer formed on said pinned layer;
a multi-layered composite free layer further comprising:
a layer of CoFeₓ B_{y}
a layer of non-magnetic material between 0 and 15 angstroms in thickness;
a layer of NiFe_{z}
a capping layer formed on said free layer; wherein,
the thickness of said non-magnetic layer determines the coupling energy between said layer of CoFeₓ B_{y} and said layer of NiFe_{z}; and wherein
x is an atomic percent of Fe and is between approximately 0 and 70 and
y is the atomic percent of B and is between approximately 0 and 30 and
z is an atomic percent of Fe and is between approximately 0 and 100.

13. The sensor of claim 12 where said non-magnetic layer is a layer of Hf, V, Zr, Nb, Ta, Mo or Cr.

14. A CPP GMR sensor element comprising:
a seed layer;
a pinning layer formed on said seed layer;
a pinned layer formed on said pinning layer and magnetically coupled thereto;
a conducting spacer layer formed on said pinned layer;
a multi-layered composite free layer further comprising:
a layer of CoFeₓ B_{y};
a layer of non-magnetic material between 0 and 15 angstroms in thickness;
a layer of NiFe_{z};
a capping layer formed on said free layer; wherein,
the thickness of said non-magnetic layer determines the coupling energy between said layer of CoFeₓ B_{y} and said layer of NiFe_{z}; and wherein
x is an atomic percent of Fe and is between approximately 0 and 70 and
y is the atomic percent of B and is between approximately 0 and 30 and
z is an atomic percent of Fe and is between approximately 0 and 30, whereby said layer of NiFe_{z} has a very negative magnetostriction and whereby the magnetization of NiFe_{z} is set by lapping and is coupled to the magnetization of CoFeₓ B_{y} providing a biasing thereof.

15. The sensor of claim 14 where said non-magnetic layer is a layer of Hf, V, Zr, Nb, Ta, Mo or Cr.

16. A TMR sensor element comprising:
a seed layer;
a pinning layer formed on said seed layer;
a pinned layer formed on said pinning layer and magnetically coupled thereto;
a conducting spacer layer formed on said pinned layer;
a multi-layered composite free layer further comprising:
a layer of CoFeₓ;
a layer of CoFe_{y} B_{z};
a layer of non-magnetic material between 0 and 15 angstroms in thickness;
a layer of NiFeₐ;
a capping layer formed on said free layer; wherein,
the thickness of said non-magnetic layer determines the coupling energy between said layer of CoFeₓ B_{y} said layer of layer of CoFeₓ and said layer of NiFe_{z}; and wherein
x is an atomic percent of Fe and is between approximately 0 and 100 and
y is an atomic percent of Fe and is between approximately 0 and 70 and
z is the atomic percent of B and is between approximately 0 and 30 and
a is an atomic percent of Fe and is between approximately 0 and 100.

17. The sensor of claim 16 where said non-magnetic layer is a layer of Hf, V, Zr, Nb, Ta, Mo or Cr.

18. A CPP GMR sensor element comprising:
a seed layer;
a pinning layer formed on said seed layer;
a pinned layer formed on said pinning layer and magnetically coupled thereto;
a conducting spacer layer formed on said pinned layer;
a multi-layered composite free layer further comprising:
a layer of FeNiₓ;
a layer of CoFe_{y} B_{z};
a layer of non-magnetic material between 0 and 15 angstroms in thickness;
a layer of NiFeₐ;
a capping layer formed on said free layer; wherein,
the thickness of said non-magnetic layer determines the coupling energy between said layer of NiFeₐ, said layer of FeNiₓ and said layer of CoFe_{y} B_{z}; and wherein
x is an atomic percent of Ni and is between approximately 0 and 40 and
y is an atomic percent of Fe and is between approximately 0 and 70 and
z is the atomic percent of B and is between approximately 0 and 30; and
a is an atomic percent of Fe and is between approximately 0 and 100.

19. The sensor of claim 18 where said non-magnetic layer is a layer of Hf, V, Zr, Nb, Ta, Mo or Cr.

20. A method of forming a CPP GMR sensor element having in-stack free layer biasing and a varying coupling energy between ferromagnetic layers of a composite free layer comprising:
providing a seed layer;
forming a pinning layer on said seed layer;
forming a pinned layer on said pinning layer;
forming a conducting spacer layer on said pinned layer;
forming a multi-layered composite free layer on said tunneling barrier layer, said formation further comprising:
forming a layer of CoFeₓ B_{y} on said tunneling barrier layer;
forming a layer of non-magnetic material between 0 and 15 angstroms in thickness on said layer of CoFeₓ B_{y};
forming a layer of NiFe_{z} on said layer of non-magnetic material;
forming a capping layer on said free layer; wherein,
x is an atomic percent of Fe and is between approximately 0 and 70 and
y is the atomic percent of B and is between approximately 0 and 30 and
z is an atomic percent of Fe and is between approximately 0 and 15, whereby said layer of NiFe_{z} has a very negative magnetostriction; then
setting a magnetization of NiFe_{z} parallel to an ABS of said sensor by lapping said ABS of said sensor, whereby said magnetization is coupled to a magnetization of CoFeₓB_{y} providing a biasing thereof .

21. The method of claim 20 where said non-magnetic layer is a layer of Hf, V, Zr, Nb, Ta, Mo or Cr.

22. The method of claim 20 wherein the energy of said coupling between said magnetization of NiFe_{z} and said magnetization of CoFeₓB_{y} is varied by varying the thickness of said non-magnetic layer.
